(19) United States
(12) Patent Application Publication
(10) Pub. No.: US 2021/0083649 A1
(43) Pub. Date: Mar. 18, 2021

(54) WAFER ARRANGEMENT, METHOD OF MAKING SAME AND HYBRID FILTER

(71) Applicant: RF360 EUROPE GMBH, Munich (DE)

(72) Inventors: Maximilian SCHIEK, Puchheim (DE); Roland ROSEZIN, Bernau a. Chiemsee (DE)

(21) Appl. No.: 16/772,418

(22) PCT Filed: Nov. 13, 2018
(86) PCT No.: PCT/EP2018/081073

§ 371 Date: Jun. 12, 2020

(30) Foreign Application Priority Data
Dec. 21, 2017 (DE) 10 2017 130 926.8

(51) Int. Cl. H03H 9/25; H03H 9/02; H03H 9/64; H03H 3/08

(52) U.S. Cl. CPC H03H 9/25; H03H 3/08; H03H 9/64; H03H 9/02535

(57) ABSTRACT

A wafer arrangement comprises a carrier wafer (CW) having a top surface divided into a regular pattern (RP) of first CA (SA1, ARS) and second surface areas (SA2, PES), wherein each first surface area is assigned to an adjacently applied respective separate second surface area to form together a combined filter area. Spots of thin film piezoelectric material are bonded to the first surface areas. Circuits of LC elements (PES) are formed integrally on the second surface areas from a multi-level metallization (ML1, ML2). The LC elements of each metallization level being embedded in a dielectric.

To meet the 5^{th} generation (5G) mobile communication standards, bandpass filter functions at increased operating frequencies and with high bandwidth are required.

Acoustic filters classically have a ladder-type or a lattice structure. In the ladder-type structure series resonators and shunt resonators are combined to generate a desired filter function e.g. a band pass function. In lattice structures, two series signal lines with series resonators are interconnected with parallel branches wherein parallel resonators are arranged respectively. An achievable bandwidth of such filter structures can be estimated to be about two times the pole-zero distance PZD of the used resonator. Standard topologies of such filter structures use SAW resonators or BAW resonators, both comparable in their PZD.

However, with conventional ladder-type bandpass filters required bandwidth and selectivity cannot be achieved at the same time.

LC elements may also be used for forming filter structures. The bandwidth of LC filters is higher, but due to the lower Q factor the pass band that is achievable has skirts that are less steep than those of the acoustic resonators in SAW or BAW technology.

To further improve the performance of the critical skirt of filter pass band, acoustic resonators are used in combination with LC elements to enhance the steepness of the skirt, thereby retaining the high bandwidth.

A recent approach to improve the quality of LC elements is described in the published patent application US 2017/0077079 A1. There, a glass substrate is used for building up high Q LC elements in a multi-level metallization embedded in a dielectric. Vias are used to interconnect different metallization levels and to improve the integration factor. In the following context those LC elements are called POG (passives on glass).

Recently a high performance SAW device called thin film SAW (TFSAW) has been proposed to provide low loss wave propagation. TFSAW are formed from a thin film piezoelectric layer arranged on a carrier substrate like Si, glass or ceramic. The arrangement can be manufactured by wafer bonding a piezoelectric single crystal wafer to a carrier wafer and thinning the crystal wafer to a desired low thickness of about 1 μm.

To form a hybrid filter by combining a TFSAW structure and an LC structure it would be necessary to use two distinct and thus separate wafers to realize the combination. Two dies lead to a significant area consumption which is undesired and may be critical in mobile or handheld devices.

It is an object of the present invention to provide a hybrid filter that overcomes the above-mentioned problems.

This and other objects are met by a wafer arrangement according to claim 1. Further embodiments of the invention are subject of further claims.

The general idea of the invention is to arrange spots of a thin film piezoelectric material and circuits of LC elements together on a common carrier wafer. The carrier wafer has at least an electrically isolating top surface that is divided into a regular pattern of first and second surface areas. Each first surface area is assigned to a respective second surface area directly adjacent to the respective first surface area. A respective first surface area and the assigned adjacent second surface area form together a combined filter area. The spots of thin film piezoelectric material are bonded to the first surface areas and each circuit of LC elements is formed integrally on a respective second surface area from a multilevel metallization. The LC elements of each metallization level are embedded in a dielectric.

Each spot provides an area of piezoelectric thin film that corresponds to the area of at least one SAW device to be manufactured on the spot. Each later SAW device requires an area that is referred to as a virtual functional chip section of the thin film piezoelectric material. However, a spot may comprise a higher number of functional chip sections.

Each second surface area comprises an area sufficient for at least one LC circuit that is referred to as a virtual passive element section. The LC circuit is part of a combined filter further comprising the respective SAW device.

A dimension of a spot and the arrangement of functional chip sections and passive element sections depends on the precondition, that in the regular pattern of the carrier wafer each virtual functional chip section on the first surface areas needs to be adjacent to a respective passive element section and that all first surface areas have to be occupied with spots. Preferably, the spots are large to comprise as many virtual functional chip section as possible.

The dimensions of the regular pattern are selected dependent on the required area for a later combined filter. Each section is preferably a rectangular or a square. A combined filter or hybrid filter comprises a thin film SAW device that is formed on a respective virtual functional chip section on a spot of the thin film piezoelectric material and an assigned circuit of LC elements interconnected with the SAW device.

The hybrid filter combines two different technologies. According to the area requirements the first surface area may differ in size from the second surface area. Hence, regular pattern means an alternating sequence of first and second surface areas arranged in two dimensions on the carrier wafer.

The regular pattern may comprise a checkerboard pattern formed by virtual functional chip sections and respective virtual passive element sections. Onto each functional chip section a thin film SAW device may be bonded and onto each virtual passive element section a respective LC circuit may be formed. In each row of the checkerboard pattern first and second surface areas are alternating and each first and second surface area in the row comprises just one SAW device and one LC circuit that is required for forming a combined or hybrid filter. The same alternating sequence is present in every column of the regular pattern. For the checkerboard pattern first and second surface areas need to have the same size.

Another possible regular pattern comprises first and second parallel stripes, where each first stripe comprises a row of thin film SAW devices and each second stripe comprises a row of LC circuits. First and second stripes are adjacent to each other such that each first surface area is adjacent to a second surface area. Each stripe can have a length according to the diameter of the carrier wafer. However, smaller stripes, i.e. shorter stripes, are possible too.

In a further possible arrangement, first and second stripes are arranged such that a first and an adjacent second stripe form a first pair of stripes. A second pair of a second and an adjacent first parallel stripe is mirror-inverted relative to the first pair. First and second pairs of stripes are arranged alternatingly. In this pattern the smallest recurring unit comprises four parallel stripes that are two adjacent first stripes and second stripes adjacently arranged on both sides of the two first stripes.

The arrangement of first and second stripes allows to independently select a required dimension for first and second surface areas respectively for virtual functional chip sections and virtual passive element sections.

The proposed wafer arrangement has the great advantage that the size of the carrier wafer can be chosen to be as large as possible and is independent from the size of a functional wafer from which the spots of thin film piezoelectric materials are cut. As a consequence and further advantage, the completion of the hybrid filters on the carrier wafer can be done in parallel for a higher number of devices than is possible on a functional wafer.

In a first step of manufacture such a wafer arrangement, spots of piezoelectric material are bonded to the carrier wafer. The spots of piezoelectric material have a first thickness d1 that is higher than the second thickness d2 of the later thin film SAW device.

If a spot of piezoelectric material bonded onto the carrier wafer comprises more than one thin film SAW device, it is preferred to provide the thin film piezoelectric material with a pattern of separation lines to facilitate the later singulation of the completed single hybrid filter chips. The separation lines are cut into the bottom surface of the spots that is the surface that is bonded to the carrier wafer.

The depth of the separation lines can range from about half the layer thickness of the thin film piezoelectric material up to the total thickness thereof. The spots that have an area complying with a higher number of virtual functional chip sections can be handled and bonded without any problem due to the relative high thickness thereof. In a later step a final thickness d1 where d1<d2 is set achieved as a result of a thinning process of the spots.

According to an embodiment the electrode structures of the thin film SAW devices manufactured on and in the first surface areas above each virtual functional chip section are enclosed in a cavity under between a capping layer of a thin film package and the surface of the thin film piezoelectric material.

The capping layer may enclose the total thin film SAW device within a single cavity. But as the SAW device usually comprises a series of resonators, it is preferred to arrange one or more resonators separately within a respective cavity. Hence, each SAW device comprises a number of cavities under the capping layer.

The LC elements of the multilevel metallization may be embedded in an organic dielectric. According to another embodiment the dielectric may be a ceramic or another inorganic dielectric. Further, it is possible to use different dielectrics for different metallization levels stacked one above the other. A preferred inorganic dielectric is an oxide such as silicon dioxide.

The LC elements that are formed in the same metallization level may be electrically connected by conductor lines. LC elements that are formed in different metallization levels may be interconnected by vias.

The thin film SAW devices may be electrically connected to an LC circuit, respectively by top conductor lines guided on top of the thin film SAW device and on top of the uppermost dielectric of the LC circuit. LC elements that need two or more metallization levels may have an additional or alternative electrical connectivity formed by a bottom conductor line.

A method of manufacturing the wafer arrangement is also within the scope of the invention. The method comprises the steps:

a) providing a functional wafer comprising a crystalline functional layer

b) dividing the functional wafer into a regular array of virtual functional chip sections and separating the functional wafer (W1) into smaller spots, each spot comprising
a single functional chip section only, or
a stripe with several functional chip sections arranged in a row, or
a stripe with functional chip sections arranged in two parallel rows,

c) providing a carrier wafer

d) dividing a main surface of the carrier wafer into a regular array of virtual carrier chip sections, each carrier section comprising area for a virtual functional chip section and a virtual passive element section

f) bonding the spots to the main surface of the carrier wafer such that
each functional chip section of a spot totally covers a first surface area of a respective virtual carrier chip section while the second surface area of the respective functional chip section is left exposed

g) reducing the thickness d1 of the functional layer of all spots until a thin film functional layer of a desired thickness d2 in each spot is achieved.

Preferably the functional wafer is a piezoelectric wafer cut from a crystalline bar. The virtual functional chip sections are of an area that is required for forming the thin film SAW device thereon. Hence, the virtual functional chip sections are the smallest unity of the functional wafer and the later wafer arrangement.

The carrier wafer may have an area larger than the area of the functional wafer because there are no restrictions due to crystal growth. The virtual carrier chip section is an area that is required for forming the hybrid filter thereon comprising a circuit of LC elements and a thin film SAW device. Within a virtual carrier chip section the areas of first and second surface area may be the same or may differ.

The size and dimension of the spots may be the same. But it is also possible that the spots have different sizes or dimensions but are arranged to form the above-mentioned arrangement of a stripe with a single row or with a stripe comprising two parallel rows adjacent to each other. This is because of the size of carrier wafer and functional wafer which may differ by a factor of greater than 2 such that the number of carrier chip sections on the carrier wafer is greater than the number of functional chip sections that can be retrieved from one functional wafer. Dividing a functional wafer into the mentioned spots results in spots of different size because of the round form of the functional wafer. Hence, arranging the spots of functional wafer material onto the carrier wafer results in a kind of mosaic.

The bonding of the spots to the main surface of the carrier wafer can be made in a single bonding step for all spots at the same time. According to a variant, each spot may be bonded separately to the carrier wafer.

Reducing the thickness of the functional layer of all spots is done after bonding spots to the carrier wafer such that all first surface areas are covered by a functional chip section.

The thickness of the functional layer of all spots may be reduced by a grinding method followed by a chemical mechanical polishing (CMP).

In a following step h) a circuit of LC elements is formed on the exposed second surface area of each virtual carrier chip section. This circuit is a first partial circuit of a combined or hybrid filter.

According to a variant of the method the thin film piezoelectric material is polished after producing the second partial circuit comprising LC elements. Thereby any impurity due to the LC production on top of the piezoelectric material may be removed.

In a following step i) that may be performed after step h) a second partial circuit of the hybrid filter comprising a circuit of SAW resonators is produced on each of the functional chip sections.

According to an alternative embodiment the of sequence steps h) and i) may be interchanged.

In a following step k) first and second partial circuits on each of the carrier chip sections are connected to form a combined filter circuit that is a hybrid filter. Alternatively, the interconnection is achieved in an integral process of forming first or second partial circuit.

In a later step, the carrier wafer is separated into single carrier chip sections by dicing. Each carrier chip section then comprises a working hybrid filter that may be provided with a package later on. According to a variant the packaging of the thin film SAW devices may be made on the wafer stage before separating the carrier wafer into single carrier chip sections.

Forming a thin film package for the SAW devices comprises applying and structuring a sacrificial layer of a material that may be easily removed in a later step. Such a sacrificial layer may be an organic material or may comprise a silicon oxide.

After structuring sacrificial material remains on those areas only that need to be enclosed under a cavity of the package. As already mentioned each cavity may comprise one or more single resonators therein.

Onto the structured sacrificial material a capping layer is produced to seal to the surface of the piezoelectric material. In a next step openings are formed and the sacrificial material is removed through these openings. After closing the openings a further capping layer may be applied.

According to further embodiments the SAW devices may be packaged in another way, for example by mounting a rigid cap thereon or by bonding a lid of the total arrangement before separating and singulating the single carrier chip sections.

In the following the invention is explained in more detail with reference to specific embodiments and the accompanying figures. The figures are schematic only and are not drawn to scale such that single parts of the figures may be depicted as greater than they really are for better understanding. Hence neither absolute nor relative dimension can be taken from the figures.

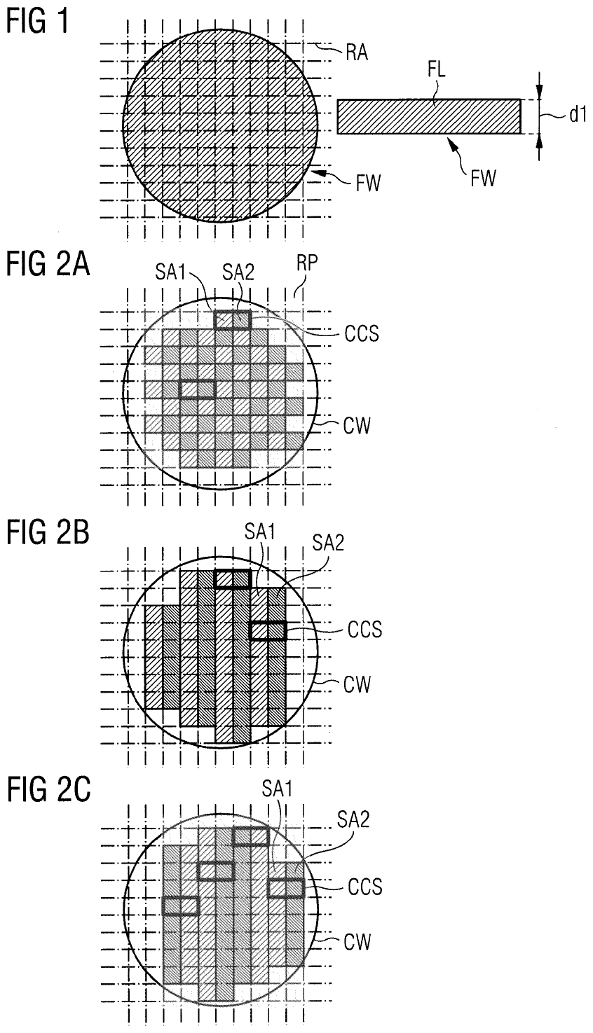

FIG. 1 shows a functional wafer in a top view and in a cross-sectional view;

FIG. 2A shows a schematic top view of a carrier wafer with a checkerboard pattern of first and second surface areas;

FIG. 2B shows a carrier wafer with a regular pattern comprising rows of functional chip sections in a top view;

FIG. 2C shows a carrier wafer with a regular pattern comprising stripes of two parallel rows of functional chip sections in a top view;

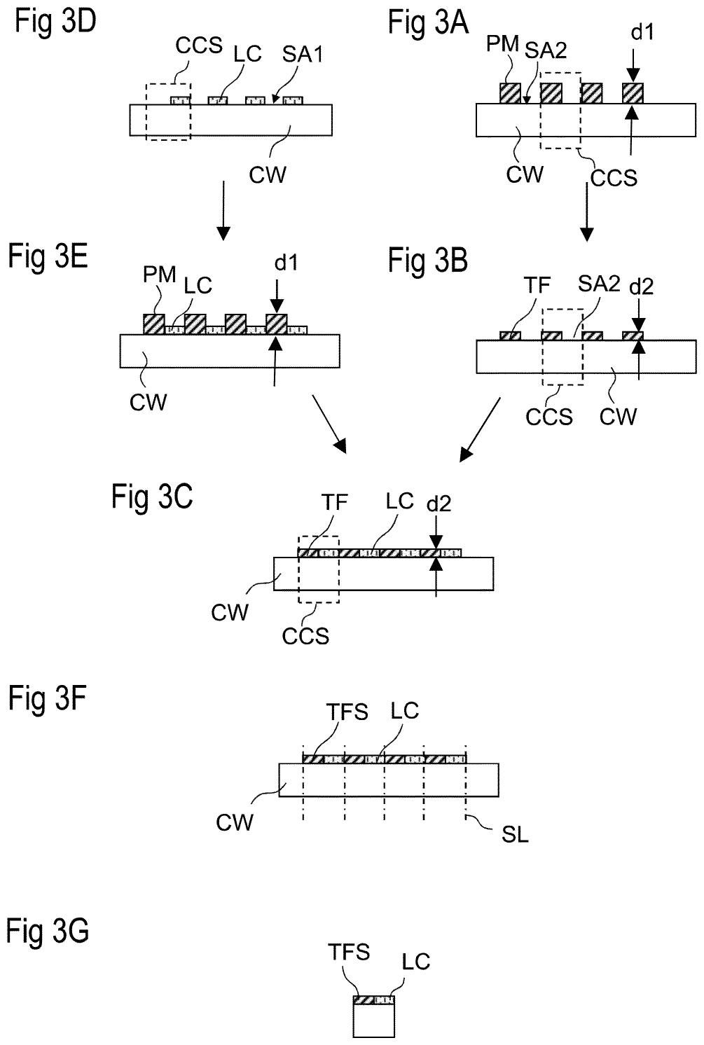

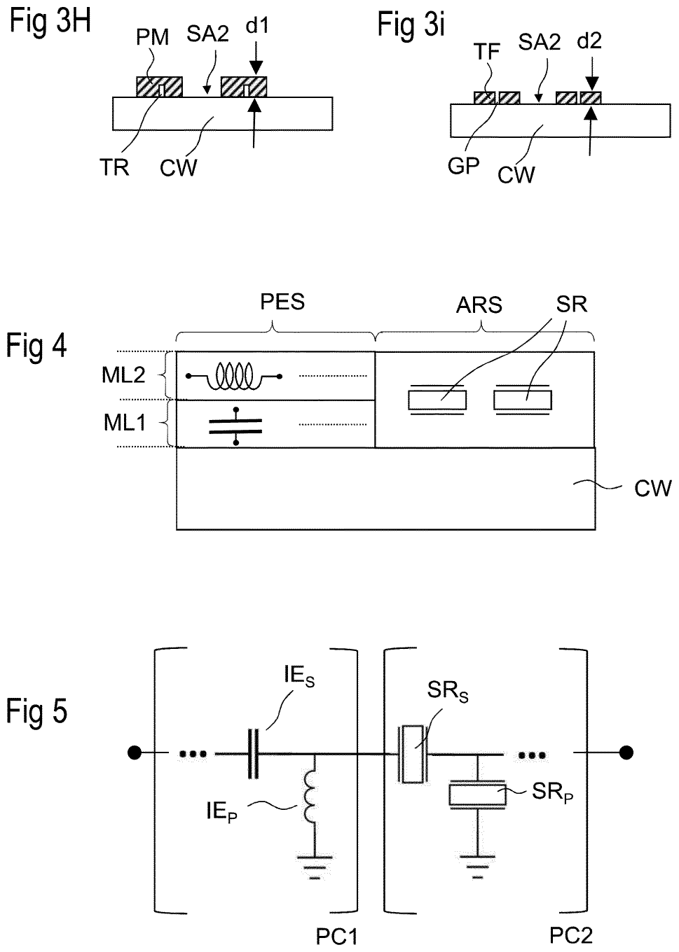

FIG. 3A to 3i show different stages of a manufacturing process in a cross-sectional view;

FIG. 4 is a schematic cross-section through a hybrid filter;

FIG. 5 is a block diagram of a first and a second partial circuit of LC elements and acoustic resonators;

FIG. 6 is a more detailed cross-section through a multilevel metallization comprising a circuit of LC elements;

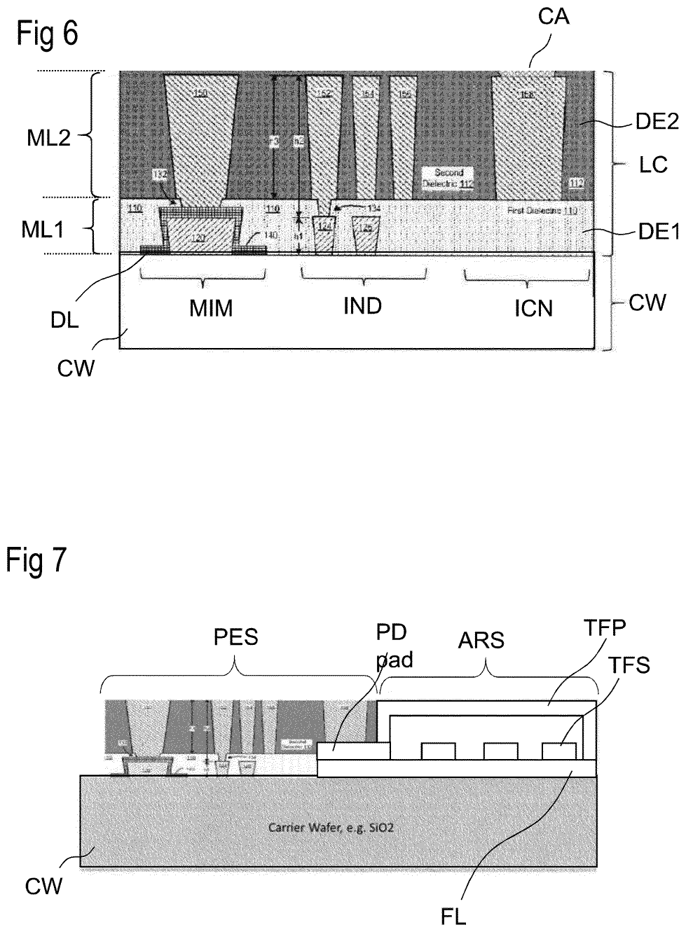

FIG. 7 shows a cross-section through a hybrid filter comprising interconnected first and second partial circuits,

FIG. 8 is a block diagram of a ladder-type filter from acoustic resonators;

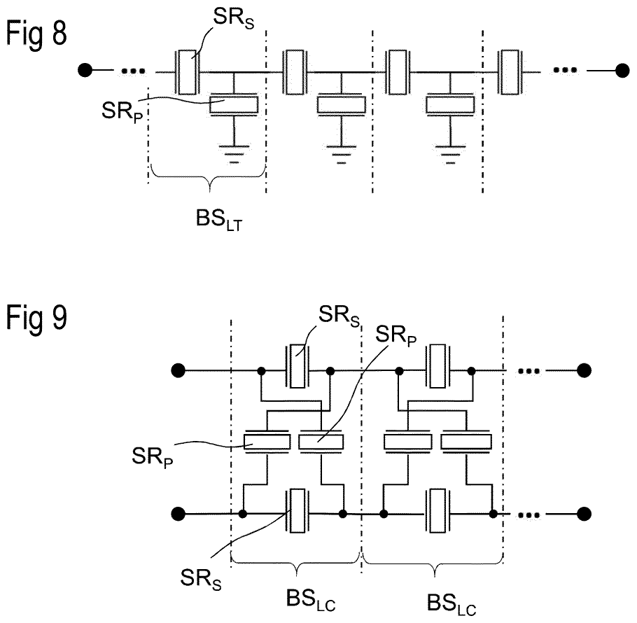

FIG. 9 is a block diagram of a lattice filter of acoustic resonators.

A method for producing a wafer arrangement starts with a functional wafer FW. The functional wafer FW is divided into a regular array of virtual functional chip sections FCS shown in the top view on the left side of FIG. 1. The according cross-section through the functional wafer FW is shown on the right side of FIG. 1. The functional wafer has a thickness d1.

In the next step the functional wafer FW is separated into smaller sized spots such that each spot comprises
a single functional chip section only, or
a stripe with several functional chip sections arranged in a row, or
a stripe with functional chip sections arranged in two parallel rows.

From one functional wafer different sized spots can be retrieved. However, it is preferred to retrieve spots that comprise a maximum number of functional chip sections to facilitate the handling of the spots.

Independently therefrom carrier wafer CW is divided into a regular pattern (RP) of carrier chip sections (CCS), each carrier chip section comprising a first surface area SA1 and a second surface area SA2.

FIGS. 2A to 2C show different arrangements of first and second surface areas and respective carrier sections comprising a first and a second surface area.

FIG. 2A show a carrier wafer where first and second surface areas SA2, SA2 are arranged in a checkerboard pattern. This means that in a horizontal row first and second surface areas are alternating. In each vertical column first and second surface areas are alternating too such that each row is shifted against the adjacent row. A first and an adjacent second surface area SA1, SA2 form a virtual carrier chip section CCS. In the figure, only two such virtual carrier chip section CCS are marked with a thick-lined rectangular.

FIG. 2B shows a carrier wafer CW with the second arrangement of first and second surface areas SA1, SA2. The row of first surface areas SA1 and a row of second surface areas SA2 are arranged in an alternating sequence parallel to each other. The rows are dimensioned to cover a maximum amount of the carrier wafer CW such that a maximum number of carrier chip sections CCS is retrieved.

FIG. 2C shows a third possible arrangement where first surface areas SA1 are arranged in two adjacent parallel rows. Between two pairs of rows two rows of second surface areas are inserted such that carrier chip sections CCS are formed each comprising a first surface area SA1 and an adjacent second surface area SA2.

Onto such a divided carrier wafer CW spots of piezoelectric material cut from the functional wafer FW are arranged that each first surface area SA1 is covered by a virtual functional chip section of a spot of piezoelectric material. To cover all first surface areas SA1 of the carrier wafer with the respective virtual functional chip section FCS, different sized spots of piezoelectric materials can be used. This means that any of the rows of first surface areas of FIGS. 2B and 2C can be covered by a number of different spots where each spot can comprise one or more virtual functional chip sections FCS.

FIG. 3A shows a cross-section of a carrier wafer CW provided with spots of piezoelectric material PM according to an arrangement as shown in FIG. 2A or 2B. The piezoelectric material PM has the original thickness d1 of the original functional wafer FW. To achieve a thin film piezoelectric material TF, the thickness of the spots of piezoelectric material PM is reduced to a thickness d2. FIG. 3B shows the arrangement at this stage.

In the next step on each exposed second surface area SA2 of FIG. 3B a circuit of LC elements is formed. The LC elements form a first partial circuit of the desired hybrid filter. FIG. 3C shows a cross-section through the carrier wafer at this stage where first surface areas are covered by thin film piezoelectric material and second surface areas are covered by a circuit of LC elements LC.

Another embodiment comprises a sequence of steps and stages as shown in FIGS. 3D, 3E and 3C. The method starts with a carrier wafer as shown in FIG. 2. Onto the second surface areas SA2 thereof circuits of LC elements LC are produced and first surface areas SA1 are left exposed as shown in FIG. 3D.

Into these exposed first surface areas spots of piezoelectric material PM of a thickness d1 are arranged and bonded to the carrier wafer CW. FIG. 3E shows the arrangement at this stage.

After thinning the spots of piezoelectric material PM to a thickness d2 an arrangement according to FIG. 3C is achieved. This stage complies with the respective stage of the first variant.

According to an alternative embodiment not shown in the figures the arrangement shown in FIG. 3B is subjected to a process of forming thin film SAW devices TFS on the spots of thin film piezoelectric material.

A further intervening step comprises packaging the thin film SAW devices TFS with a thin film SAW package that leaves pads PD of the thin film SAW devices TFS exposed for electrical interconnection with the later circuit of LC elements.

Electrical contact can be made integrally when producing the circuit of LC elements LC.

In a step following the stage shown in FIG. 3B or 3C thin film SAW devices TFS are produced by forming metallic electrode structures on the top surface of the thin film piezoelectric material TF. Then, the thin film SAW devices TFS of a carrier chip section are connected with the respective circuit of LC elements LC of the same carrier chip section CCS by respective conductor lines. In this way a hybrid filter is achieved in each carrier chip section CCS comprising a thin film SAW device and a respective circuit of LC elements.

In a later step the thus produced hybrid filters are singulated by dicing the carrier chip and the respective structures formed thereon along separation lines SL, as shown in FIG. 3F.

FIG. 3G shows a single hybrid filter comprising exact one carrier chip section CCS comprising a thin film SAW device TFS and an interconnected circuit of LC elements LC.

Alternatively packaging of the hybrid filters can be done at the stage as shown in FIG. 3F. The packaging is not shown in the figures.

FIGS. 3H and 3i show a preferred method of handling spots of piezoelectric material PM comprising more than one functional chip section FCS. To ease the later separation into single chips the spots are provided with trenches TR at the bottom surface thereof. The trenches divide adjacent functional chip sections. As shown in FIG. 3H each trench TR may have a thickness between d1 and d2 but leaves sufficient mechanical stability to the spot for secure handling thereof.

FIG. 3i shows the arrangement after thinning the piezoelectric material PM to a thickness d2. Hereby the trenches are exposed from the top and form gaps GP between adjacent functional chip sections of thin film piezoelectric material TF. Second surface areas SA2 on the carrier wafer CW remain exposed. A step of polishing the surface may follow.

FIG. 4 schematically shows a hybrid filter. The hybrid filter comprises a passive element section PES and an acoustic resonator section ARS. The acoustic resonator section ARS comprises a circuit of SAW resonators that form a SAW device that is a second partial circuit of a hybrid filter. Exact structures of the SAW device that forms a second partial circuit PC2 of the hybrid filter are not shown.

The passive element section PES comprises several metallization levels ML1, ML2, two of which are shown in FIG. 4. In a first metallization level ML1, for example, a capacitor MIM may be formed. In the second metallization level ML2 an inductance or coil may be formed and interconnected with the passive elements of the first metallization level ML1 by vias. Alternatively the structures of the first metallization level ML1 to be connected with structures of the second metallization level ML2 need to be exposed after embedding the first metallization level ML1 in a dielectric. The figure does not show the conductor lines and vias connecting passive elements of the passive element sections PES and the SAW resonators SR of the acoustic resonator sections ARS.

FIG. 5 shows a block diagram of a hybrid filter with a minimum number of elements. A real circuit may comprise a higher number of such structures. In FIG. 5 a first partial circuit PC1 comprises a series impedance element IE_{S} and a parallel impedance element IE_{P}. The series impedance element IE_{S} can be embodied as a capacitor and the parallel impedance elements IE_{P} can be embodied as a coil. A second partial circuit PC2 comprises at least one series SAW resonator SR_{S} and at least one parallel SAW resonator SR_{P}. Within the combined circuit first and second partial circuits PC1, PC2, as shown in FIG. 5, can alternate or be arranged in an arbitrary sequence. The exact design of such a hybrid filter can be optimized according to the requirements of the desired hybrid filter. Such an optimization can easily be done by a skilled worker by means of an optimizing computer program.

FIG. 6 shows a schematic cross-section through the passive element section PES of a hybrid filter. This passive element section may be formed according to a method as described in the above-mentioned US 2017/0077079 A1. On a carrier wafer CW that is preferably a plane glass wafer, first LC elements are formed and embedded in a first dielectric DE1. In the figure a LC elements is embodied as a metal-isolator-metal capacitor MIM that is a first metal structure covered by a dielectric layer DL and a further metal structure as a second capacitor electrode.

Above the first dielectric DE1 a second metallization level ML2 is formed, structured and embedded in a second dielectric DE2. Both dielectrics DE1 and DE2 may be identical for both metallization levels or different. One element of the capacitor MIM may be structured in the second metallization level as the top electrode.

The metal structures may be made of Al or an AlCu alloy. The dielectric layer DL may be an oxide like silicon oxide.

Above the first dielectric DE1 a second metallization level ML2 is formed, structured and embedded in a second dielectric DE2. Besides the top electrode of the capacitor MIM, a coil IND is structured from the second metallization level ML2. For forming a planar coil IND a single mask step is used to structure the second metallization level ML2 accordingly.

Structuring a metallization level ML can be done by first forming and structuring a resist mask and then depositing a metal in areas exposed by the resist mask. Deposition of a metal may be done by plating a metal onto a seed layer that is applied onto the entire surface of substrate SU for the first metallization level or onto the first dielectric DE1 or a higher level of dielectric. After the plating step the resist mask is removed thereby exposing remaining seed layer areas that are then removed as well.

A three-dimensional coil IND (not shown in the figure) needs to be formed within two neighboured metallization levels. One of them may be the first metallization level ML1.

For interconnecting the two metallization levels ML1, ML2 a respective metallization in the lower metallization level ML1 is exposed by forming an opening in the top surface of the first dielectric DE1. Structures of the second metallization level ML2 applied thereon can now contact respective structures in the first metallization level ML1. All structures that need not have an electrical inter-level connection are isolated against each other by the first dielectric DE1.

A circuit of LC elements LC is integrally formed in a two-level metallization.

In an area of interconnection ICN a via may provide electric contact between different metallization levels and a contact area CA the top surface of the circuit of LC elements. Alternatively, an electrical interconnection of the LC circuit is provided at the bottom by a conductor line on the top surface of the carrier wafer or at any higher level dependent on the structures present on the carrier wafer CW.

FIG. 7 shows a cross-section through a carrier chip section CCS of the wafer arrangement that may be singulated from the wafer arrangement. As already shown schematically in FIG. 4, the combined filter circuit is arranged on a carrier wafer CW and comprises a passive element section PES and an acoustic resonator section ARS. The acoustic resonator section ARS comprises a thin film SAW device TFS that is achieved by providing electrode structures on top of the functional layer FL of the thin film piezoelectric layer layer. The thin film SAW device TFS is enclosed by a thin film package TFP providing a cavity enclosing the electrode structures of the thin film SAW device.

The thin film package TFP may expose a pad PD connected to the electrode structures of the thin film SAW device TFS to enable electrical contact to the circuit of LC elements arranged in the passive element section PES. In this embodiment the thin film SAW device TFS is completely packaged before manufacturing and depositing the multilevel metallization of the circuit of LC elements in the passive element section PES. In the figure a metallic structure of the second metallization level ML2 is in direct contact with the pad PD to interconnect passive element section PES and acoustic resonator section ARS.

The acoustic resonator section ARS may comprise a circuit of thin film SAW resonators SR connected in a ladder-type or a lattice-type topology as shown schematically in FIGS. 8 and 9.

FIG. 8 shows a ladder-type arrangement comprising series SAW resonators SR_{S} and parallel SAW resonators SR_{P}. In this embodiment a respective series SAW resonator SR_{S} and an according parallel SAW resonator SR_{P} form a basic section BS_{LT} of the ladder-type arrangement. A ladder-type arrangement comprises a number of basic sections BS_{LT} that can be circuited in series to achieve a desired filter function of a second partial filter circuit PC2.

FIG. 9 shows a lattice-type arrangement of SAW resonators comprising series and parallel SAW resonators. In contrast to the ladder-type arrangement, the parallel SAW resonators SR_{P} are arranged in parallel branches that interconnect two series signal lines with series SAW resonators SR_{S}. The parallel branches are circuited in a crossover arrangement such that the basic section of the lattice-type arrangement BS_{LC} comprises a first and a second series SAW resonator SR_{S} arranged in two different signal lines and two crossover circuited parallel branches with a respective parallel SAW resonator SR_{P} arranged therein. A lattice-type filter may also comprise a number of basic sections according to the filter requirements.

The invention has been explained by a limited number of examples only and is thus not restricted to these examples. The invention is defined by the scope of the claims and may deviate from the provided embodiments.

Such further embodiments may comprise further details not shown in the presented embodiments. Further, the wafer arrangement and also every hybrid filter may comprise an arbitrary circuit of LC elements and SAW devices of an arbitrary structure. The hybrid filter may realize an arbitrary one of a series of different filter functions. Examples are bandpass, high pass and low pass as well as combined filters like an extractor, duplexer or multiplexer.

List of used reference symbols

| | |
|---|---|
| ARS | acoustic resonator section |
| BS_{LT}, BS_{LC} | basic section of ladder type and lattice filter |
| CA | contact area |
| CW | carrier wafer |
| d1 | first thickness (of FW) |
| d2 | second thickness (of TF) |
| DE1, DE2 | dielectric |
| DL | dielectric layer |
| FCS | (virtual) functional chip section |
| FL | functional layer |
| FW | functional wafer |
| GP | gap |
| ICN | interconnection |
| IE_{S}, IE_{P} | series and parallel impedance elements |
| IND | coil |
| LC | circuit of LC elements |
| MIM | MIM capacitor |
| ML1, ML2 | metallization levels, embedded in a |
| PC1, PC2 | first and second partial circuit of hybrid filter |
| PD | Pad |
| PES | passive element section |
| PM | spots of piezoelectric material |
| RP | regular pattern |
| SA1, SA2 | first and second surface areas |
| SL | separation lines |
| SR_{S}, SR_{P} | series and parallel SAW resonators |
| TF | thin film piezoelectric material |
| TFP | thin film package |
| TFS | thin film SAW device |
| TR | trench |

1. A wafer arrangement comprising
a carrier wafer (CW) having at least an electrically isolating top surface, which surface is divided into a regular pattern (RP) of first and second surface areas (SA1,SA2), wherein each first surface (SA1) area is assigned to an adjacently applied respective separate second surface area (SA2) to form together a combined filter area
spots of thin film piezoelectric material (TF) bonded to the first surface areas (SA1)
circuits of LC elements (LC) that are formed integrally on the second surface areas from a multi-level metallization, the LC elements of each metallization level (ML) being embedded in a dielectric.

2. The wafer arrangement of claim 1
wherein thin film SAW devices (TFS) are formed on the spots of thin film piezoelectric material (TF) such that each first surface area comprises one thin film SAW device (TFS)
wherein each thin film SAW device is electrically interconnected with an assigned circuit of LC elements (LC) to form a combined filter circuit comprising LC elements and thin film SAW devices (TFS).

3. The wafer arrangement of claim 1 wherein the regular pattern of first and second surface areas is
a) a checkerboard pattern formed by spots comprising thin film SAW devices (TFS) and circuits of LC elements, or
b) an alternating pattern of first and second parallel stripes, each first stripe comprising a row of thin film SAW devices, each second stripe comprising a row of LC circuits, or
c) a parallel arrangement of first and second stripes, wherein a first and an adjacent second stripe form a first pair of stripes, wherein a second pair of a second and an adjacent first parallel stripe is mirror-inverted relative to the first pair, and wherein first and second pairs of stripes are arranged alternatingly.

4. The wafer arrangement of claim 1,
wherein those spots of thin film piezoelectric material that comprise more than one TFSAW device are provided with a pattern of trenches (TR)
wherein the trenches are cut into the bottom surface of the spots of thin film piezoelectric material (PM) bonded to the carrier wafer
wherein the depth of the trenches ranges from half the layer thickness of the thin film piezoelectric material up to the total thickness d2 thereof such that the top surface of the carrier wafer is exposed in the separation lines from the top.

5. The wafer arrangement of claim 1, wherein the thin film SAW devices (TFS) are enclosed under a capping layer of a thin film package (TFP) providing a cavity between the thin film SAW devices (TFS) and the capping layer.

6. The wafer arrangement of claim 1, wherein the dielectric (DE) the LC elements (LC) are embedded in is an organic dielectric.

7. The wafer arrangement of claim 1, wherein the dielectric (DE) the LC elements (LC) are embedded in is an oxide such as silicon dioxide.

8. The wafer arrangement of claim 1, wherein
the LC elements (LC) are formed from a multi-level metallization,
each metallization level (ML) of the LC elements is embedded in a dielectric (DE)
LC elements that are formed in the same metallization level are electrically connected by conductor lines
LC elements that are formed in different metallization levels are interconnected by vias
the TFSAW devices are electrically connected to a LC circuit respectively by conductor lines guided on top of the thin film SAW devices (TFS) and on top of the uppermost dielectric (DE) of the multi-level metallization.

9. A method of manufacturing the wafer arrangement of claim 1, comprising the steps
a) providing a functional wafer (FW) comprising a crystalline functional layer (FL)
b) dividing the functional wafer (W1) into a regular array (RA) of virtual functional chip sections (FCS) and separating the functional wafer (W1) into smaller spots, each spot comprising
a single functional chip section only, or
a stripe with several functional chip sections arranged in a row, or
a stripe with functional chip sections arranged in two parallel rows,
c) providing a carrier wafer (CW)
d) dividing a main surface of the carrier wafer (W2) into a regular pattern of virtual carrier chip sections (CCS), each comprising area for a virtual functional chip section and a virtual passive element section
e) bonding the spots to the main surface (BS) of the carrier wafer (W2) such that
each functional chip section of a spot totally covers a first surface area of a respective virtual carrier chip section while the second surface area of the respective carrier chip section (CCS) is left exposed
f) reducing the thickness d1 of the functional layer of all spots until a thin film functional layer (TF) of a desired thickness d2 in each spot is achieved.

10. The method of claim 9
comprising a step h
h) forming a first partial circuit (PC1) of a hybrid filter from a circuit of LC elements (LS) produced on the exposed second surface (SA2) area of each such virtual carrier chip section.

11. The method of one of the claim 9, comprising a step i) performed before or after step h)
i) forming a second partial circuit of a filter circuit from a circuit of SAW resonators produced on each of the functional chip sections
k) integrally connecting first and second partial circuit on each of the carrier chip sections to form a combined filter circuit
l) separating the carrier wafer into single carrier chip sections by dicing.

12. A hybrid filter comprising a combined filter circuit singulated from a wafer arrangement of any of claims 1-8.
